(19) United States
(12) Patent Application Publication
(10) Pub. No.: US 2016/0359004 A1
(43) Pub. Date: Dec. 8, 2016

(54) STRESS CONTROL FOR HETEROEPITAXY

(71) Applicant: VEECO Instruments, Inc., Plainview, NY (US)

(72) Inventors: Jie Su, Metuchen, NJ (US); George Papasouliotis, Warren, NJ (US); Balakrishnan Krishnan, Bridgewater, NJ (US); Soo Min Lee, Bridgewater, NJ (US)

(21) Appl. No.: 14/729,741

(22) Filed: Jun. 3, 2015

(51) Int. Cl. H01L 29/15; H01L 29/205; H01L 29/20

(52) U.S. Cl. CPC H01L 29/155; H01L 29/2003; H01L 29/205

(57) ABSTRACT

Stress control using superlattice structures for epitaxy on base wafer substrates, including AlN/GaN superlattices for epitaxy of GaN on silicon {111} substrates. Crack-free GaN cap layers can be grown over superlattice structures containing AlN/GaN superlattice layers. Compressive and tensile stress can be precisely adjusted by changing the thickness of the superlattice layers and the number of superlattice layers. For a constant period thickness, growth conditions, such as growth rate of GaN, V/III ratio during AlN growth, and growth temperature, can be adjusted.

### SUMMARY

This disclosure is directed to stress control in silicon (Si) wafer based semiconductor materials using a superlattice structure that includes alternating layers of materials that include one or more of aluminum (Al), gallium (Ga), and/or nitrogen (N). The semiconductor materials include a seed layer that includes one or more of Al, Ga, and/or N on a substrate, an optional buffer structure that includes one or more of Al, Ga, and/or N on the seed layer, the superlattice structure, and a cap layer that includes one or more of Al, Ga, and/or N. The buffer structure can be composed of three or more distinct layers comprising AlₓGa₁₋ₓN, where 0≦x≦1 in some implementations, and where 0<x<1 in other implementations.

In one implementation, the stress control is via an AlN/GaN superlattice structure (SL) for epitaxy of GaN on silicon (Si) {111} substrates. A superlattice structure having at least one pair of AlN/GaN SL layers is provided on the Si substrate, on which is positioned a GaN layer. The superlattice structure can have 50 to 100 pairs of the AlN and GaN layers, where the AlN layers are 3-5 nm thick and the GaN layers are 10-30 nm thick. The thick GaN layer can be, e.g., greater than 1 micrometer thick, e.g., 2 micrometers thick.

In another implementation, the superlattice structure can have 50 to 100 pairs of the AlN and GaN, plus one additional GaN layer.

In another implementation, a semiconductor material comprises a substrate on which a seed layer is placed. A superlattice structure having a plurality of superlattice layers is on the seed layer. The superlattice layers are, in any order, (a) GaN and (b) layers selected from the group consisting of AlN, Al_{y}Ga_{1-y}N, where 0<y<1, and mixtures thereof, is on the seed layer. A cap layer is formed on the superlattice structure. In some implementations, a buffer structure is between the seed layer and the superlattice structure, the buffer structure having three or more distinct layers of AlₓGa₁₋ₓN, where 0≦x<1or 0<x<1. The substrate can be silicon (Si) or any other substrate suitable for use in metal-organic chemical vapor deposition (MOCVD), molecular beam epitaxy (MBE), or other epitaxial techniques.

Another implementation provides a semiconductor material consisting essentially of a silicon (Si) substrate on which an AlN seed layer is placed. A buffer structure, comprising three or more distinct layers of AlₓGa₁₋ₓN, where 0≦x≦1 or 0<x<1, is then placed on the AlN seed layer. A superlattice structure is then placed on the buffer structure, the superlattice structure comprising a plurality of superlattice layers in any order of (a) GaN and (b) layers selected from the group consisting of AlN, Al_{y}Ga_{1-y}N, where 0<y<1, and mixtures thereof. A cap layer is then formed on the superlattice structure. In some implementations, the buffer structure is optional.

In another implementation, a semiconductor material comprises a substrate on which a seed layer is placed. A superlattice structure comprising a plurality of superlattice layers is placed on the seed layer, each of the superlattice layers comprising one or more of Al, Ga, N, with at least one of the plurality of superlattice layers providing compressive stress and at least one of the plurality of superlattice layers providing tensile stress. A cap layer is then formed on the superlattice structure, the cap layer comprising one or more of Al, Ga, N. In some implementations, a optional buffer structure having distinct multiple layers comprising one or more of Al, Ga, N is formed between the seed layer and the superlattice structure. The substrate can be silicon or any other substrate suitable for use in metal-organic chemical vapor deposition (MOCVD), molecular beam epitaxy (MBE), or other epitaxial techniques.

Compressive and tensile stress can be precisely adjusted by changing the thickness of the AlN and GaN layers in the SL. The growth conditions of the SL layers, such as growth rate of GaN, V/III ratio during AlN growth, and growth temperature, affect wafer stress and can be controlled to provide constant period thickness.

Smooth surfaces with excellent crystal quality can be obtained; e.g., roughness of 0.18 nm in a 5×5 μm² AFM scan, and 352 and 375 arc sec FWHM for (002) and (102) XRD rocking curves, respectively. Effective dislocation filtering and sharp interfaces between the SL layers can be confirmed by transmission electron microscope (TEM) and omega-2 theta scans along GaN (004) direction. The compressive and/or tensile stress can be precisely controlled via the thickness of the SL layer.

These and various other features and advantages will be apparent from a reading of the following detailed description.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTION OF THE DRAWING

FIG. 1(a) is a schematic side view of an example semiconductor material having a substrate and a superlattice structure for stress control; FIG. 1(b) is another example semiconductor material having a substrate and superlattice structure for stress control.

FIG. 2(a) is schematic side view of an implementation of a semiconductor material showing a silicon (Si) substrate having an AlN seed layer, AlGaN buffer layers, a AlN/GaN superlattice structure, and a top GaN layer; FIG. 2(b) is a graphical representation of wave curvature and corresponding curvature during growth of the superlattice layers.

FIG. 3(a) is a photomicrograph of a GaN layer over AlN/GaN superlattice structure on Si, particularly, a 5×5 square micrometer AFM scan; FIG. 3(b) is a photomicrograph of GaN over AlN/GaN superlattice structure on Si substrate, particularly, a 20×20 square micrometer AFM scan; FIG. 3(c) is a graphical representation of RT wafer bow; and FIG. 3(d) is a graphical representation of triple-axis omega-2 theta scan along GaN (004) peak.

FIG. 4(a) is a photomicrograph of a cross-sectional TEM image of GaN over AlN/GaN superlattice structure on Si substrate; FIG. 4(b) is an enlarged cross-sectional image of the superlattice structure of FIG. 4(a).

FIG. 5(a) is a schematic side view of the superlattice layers showing compressive and tensile stress during growth of GaN and AlN layers, respectively; FIG. 5(b) is a graphical representation of an example curvature evolution during the growth of superlattice layers.

FIG. 6(a) is a graphical representation of the effect of varying the thickness of GaN superlattice layers on wafer curvature; FIG. 6(b) is a graphical representation of the effect of varying the thickness of AlN superlattice layers on wafer curvature.

FIG. 7(a) is a graphical representation of the effect of growth conditions of GaN superlattice layers on wafer stress; FIG. 7(b) is a graphical representation of the effect of V/III ratios of AlN superlattice layers on wafer stress; and FIG. 7(c) is a graphical representation of the effects of growth temperature of superlattice layers on wafer stress.

### DETAILED DESCRIPTION

The present disclosure is directed to stress control in a wafer by using a superlattice structure to counteract the tensile stress and the compressive stress of the various layers in the wafer.

In the following description, reference is made to the accompanying drawing that forms a part hereof and in which are shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples provided below.

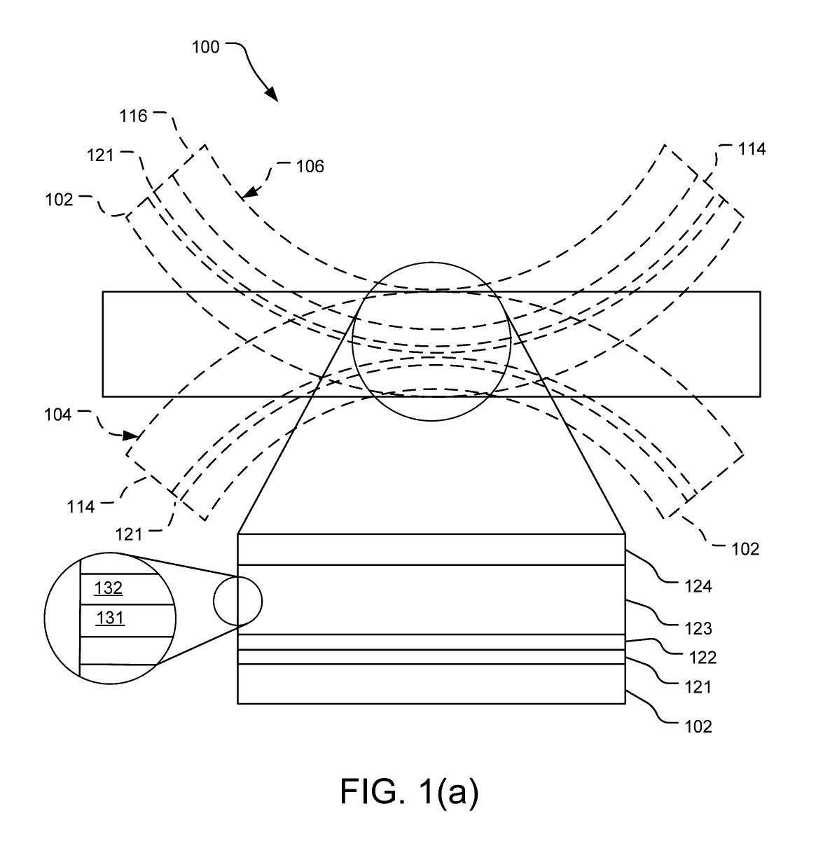

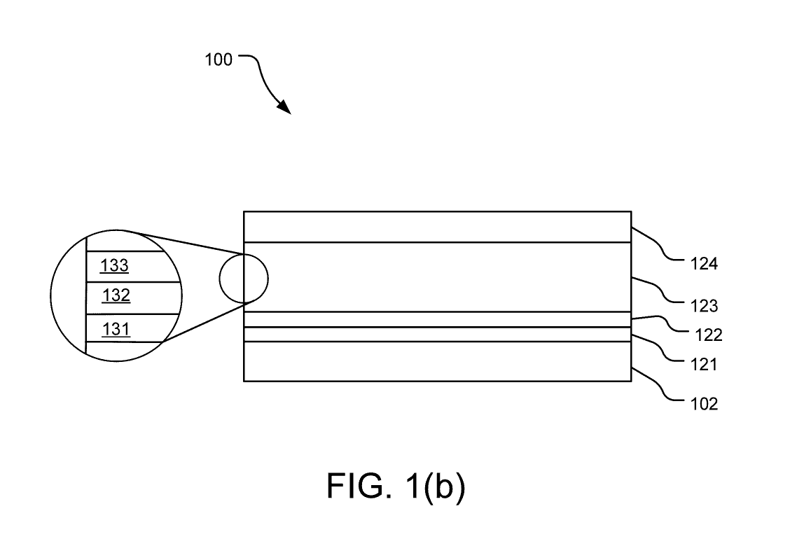

FIG. 1(a) shows a semiconductor material 100 that includes a base substrate 102 with a seed layer 121 on top thereof. FIG. 1(a) also shows, in phantom, a convex semiconductor material 104 and a concave semiconductor material 106. When a buffer structure 114, which has a lattice constant that is mismatched from the lattice constant of the substrate 102, is formed on the substrate 102 and the seed layer 121, the buffer structure 114 has a tensile stress associated with it, which causes the buffer structure 114 and the substrate 102/seed layer 121 to distort and bend in a convex manner, resulting in a convex semiconductor material 104. When a cap layer 116, which has a lattice constant greater than the buffer structure 114, is formed on the buffer structure 114, the cap layer 116 has a compressive stress associated with it, which causes the entire structure to distort and bend in a concave manner, resulting in concave semiconductor material 106. To inhibit the bending and distortion, a superlattice structure is provided between the buffer structure 114 and the cap layer 116. In some instances, the buffer structure is optional and the superlattice structure is present directly on the seed layer 121.

FIG. 1(a) also shows the substrate 102 when a superlattice structure is provided in the construction. The substrate 102 is also shown with a buffer structure 122 on the seed layer 121, the buffer structure 122 having a lattice constant that is mismatched from the lattice of the substrate 102. Formed on the buffer structure 122 is a superlattice structure 123, which is composed of alternating layers of materials having different lattice constants. The alternating layers of the superlattice structure 123 result in alternating layers of compressive stress and tensile stress. Formed on the superlattice structure 123 is a cap layer 124, which has a lattice constant matched with that of the superlattice structure 123. Together, the buffer structure 122, the superlattice structure 123 and the cap layer 124 counteract the internal stresses, resulting in a flat semiconductor material 100.

AlGaN based high-electron-mobility-transistors (HEMTs) grown on silicon (Si) substrates are the focus of considerable research efforts, due to the availability of low-cost, large-diameter substrates and the potential for integration with Si-based technologies. However, epitaxy of GaN on Si {111} is challenging because of eutectic Ga-Si reactions, and the large mismatch in lattice constant and thermal expansion coefficient (CTE) between GaN and Si. As shown in FIG. 1(a), the large lattice mismatch can result in a high density of misfit and threading dislocations in the epi-layers, along with significant intrinsic stress causing large wafer bow during growth, which, in turn, can lead to large gradients in growth temperature across the wafer, resulting in non-uniformity in epi-layer thickness, alloy composition, and device performance.

Compressive intrinsic stress can be intentionally built in to the GaN layer during epitaxy to compensate for the large tensile thermal stress that occurs during wafer cool-down. A superlattice structure, such as the superlattice structure 123 of FIG. 1(a), has been found to be effective in building compressive intrinsic stress and filter dislocations within the growth plane.

An enlarged view of the superlattice structure 123 is shown in the inset of FIG. 1(a). The superlattice structure 123 has alternating layers of materials having different lattice constant; particularly, the superlattice structure 123 shown has a first material layer 131 alternating with a second material layer 132. In some implementations, the number of first material layers 131 is the same as the number of second material layers 132, whereas in other implementations, one has one more layer.

The first material layer 131 and the second material layer 132 each have a lattice constant. One of the lattice constants is greater than the other; that is, either the first material layer 131 has a larger lattice constant than the second material layer 132, or the second material layer 132 has a larger lattice constant than the first material layer 131. In some implementations, the difference between the lattice constants is at least 0.01 Å, or at least 0.05 Å, or at least 0.06 Å, or at least 0.07 Å, or at least 0.08 Å.

The first material layer 131 and the second material layer 132 are found as alternating layers in the superlattice structure 123; at least one pair of alternating layers 131, 132 is present. In some implementations, at least 50 pairs of layers are present, e.g., about 50 to 100 pairs of layers. In other implementations, more or less pairs of layers are present. As indicated above, the layers 131, 132 can be present as pairs or as pairs plus one layer.

Each material layer 131, 132 has a thickness. Example thicknesses include from 3 nm to 30 nm, although thinner and/or thicker layers can be used. In some embodiments, the first material layer 131 and the second material layer 132 have the same thickness, whereas in other embodiments one of the layers 131, 132 is thicker than the other. The thicker layer may be, for example, at least 3 nm, or at least 5 nm, or at least 10 nm thicker than the other layers. In some implementations, the thicker layer is at least 2× thicker, or at least 3× thicker, or at least 4× thicker than the other layer. A ratio between the thicknesses of the two layers 131, 132 can be, e.g., 1:2 to 1:10.

Because of the large mismatch in lattice constant and thermal expansion coefficient (CTE) between GaN and Si, a GaN cap layer on a silicon substrate results in a warped or bent wafer due to the internal stress. A superlattice structure formed from alternating layers composed of any or all of Al, Ga, and/or N (e.g., GaN and AlN) counteracts the stress, providing a flat semiconductor material.

Example thicknesses for individual layers in the superlattice structure are 1-50 nm, such as 3-35 nm. For GaN and AlN materials, example thicknesses of the layers are 3-5 nm for AlN and 10-30 nm for GaN. GaN has a lattice constant of 3.19 Å and AlN has a lattice constant of 3.11 Å, which results in the GaN layer having compressive stress and the AlN layer having tensile strength.

In one implementation, this disclosure provides a semiconductor material formed by a silicon (Si) substrate, an AlN seed layer on the Si substrate, a buffer structure composed of multiple AlₓGa₁₋ₓN layers, where 0≦x≦1, a superlattice (SL) structure comprising at least one pair of AlN and GaN layers formed on the buffer structure, and a cap layer (e.g., GaN) formed on the SL structure. The SL structure had 50-100 pairs of AlN/GaN layers, and individual layer thicknesses were 3-5 nm for AlN and 10-30 nm for GaN. In another particular implementation, the SL structure has 50-100 pairs of AlN/GaN and one additional GaN layer.

Although an AlN seed layer on the Si substrate is described above and further below, the seed layer can be composed of any of Al, Ga, and/or N, and is selected depending on the buffer structure and/or on the superlattice structure. In some implementations, the seed layer is lattice mismatched from the Si substrate. Similarly, although a buffer structure composed of multiple layers of AlₓGa₁₋ₓN layers, where 0≦x≦1, is described above and further below, the buffer structure can be composed of any of Al, Ga, and/or N, and is selected depending on the seed layer and/or the superlattice structure. In some implementations, the buffer structure is lattice mismatched from the Si substrate.

In FIG. 1(b), another implementation of a semiconductor material is provided. Semiconductor material 200 has a base substrate 202, on which is a seed layer 221. On top of the seed layer 221 is a buffer structure 222, which can be optional. The buffer structure 222 is composed of multiple (e.g., three or more) AlₓGa₁₋ₓN layers, where 0≦x≦1 or 0<x<1. The ratio of Al and Ga differ among the multiple layers, with Al being greater in those layers closest to the seed layer 221 and Ga being greater in those layers closest to the superlattice structure 223.

The superlattice structure 223 has a plurality of layers 231, 232, 233, (a) GaN and (b) layers selected from the group consisting of AlN, Al_{y}Ga_{1-y}N, where 0<y<1, and mixtures thereof. The layers can be arranged in any order. Thus, in one example, the layers 231, 232, 233 can be Al_{y}Ga_{1-y}N/AlN/GaN, respectively. In another example, the layers 231, 232, 233 can be AlN/Al_{y}Ga_{1-y}N/ GaN. Other layering of GaN, AlN, and Al_{y}Ga_{1-y}N is also possible. The number of layers can vary, depending upon the substrate characteristics with some implementations having at least 50 sets of layers (meaning one set being one layer of each of GaN/AlN/Al_{y}Ga_{1-y}N in any order), for example, 50 to 100 sets of layers, while in other implementations, there can be fewer sets of layers.

For both the example of FIG. 1(a) and FIG. 1(b), with Al_{y}Ga_{1-y}N having varying amounts of Al and Ga, the lattice constant for AlGaN will be between the lattice constants of AlN and GaN. Thus, depending upon the semiconductor structure to be developed, the ratio of Al and Ga in the AlGaN layer can be varied, kept constant, or a combination of both, depending upon the number of sets of layers needed in the semiconductor structure. The thickness of the various layers AlGaN is similar to the AlN and GaN layers discussed herein, with the thickness of the AlGaN layers generally being between the thicknesses of the AlN and GaN layers.

Like the other implementations herein, a cap layer 224 is on top of the superlattice structure 223. The cap layer 224 can comprise one or more of Al, Ga, N. In typical implementations, the cap layer 224 will be GaN. Various active layers for a variety of semiconductor devices, for example, HEMT, can then be grown on the cap layer 224.

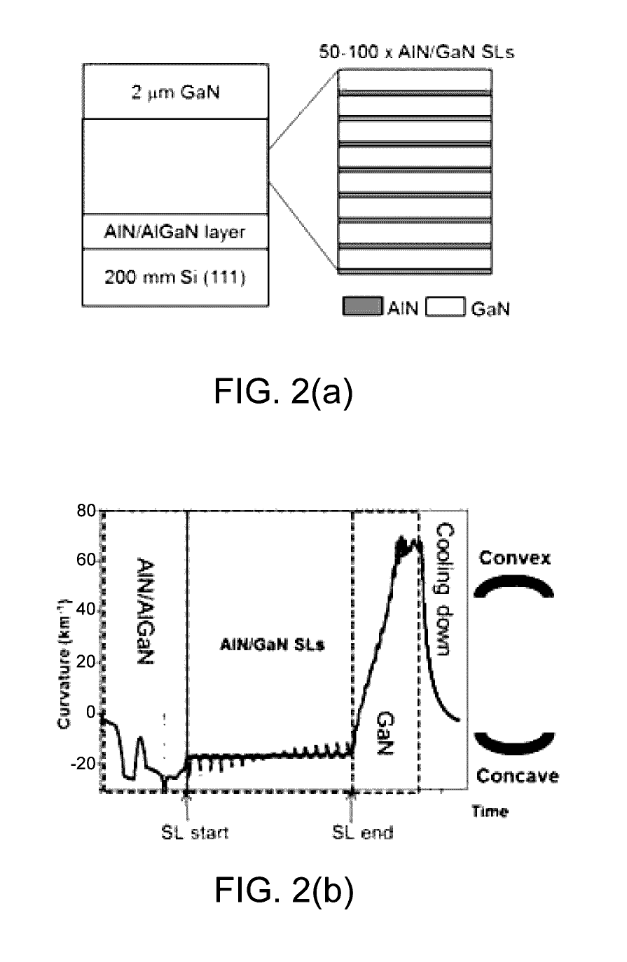

Various epitaxy process experiments were carried out in a state-of-art Veeco Propel™ Power GaN MOCVD system, which encompasses a 200 mm single wafer MOCVD reactor. The system was equipped with a DRT-210 in-situ process monitor (integrated pyrometer-reflectometer-deflectometer unit) for wafer temperature, reflectance and wafer curvature measurements. The evolution of growth stress was monitored in real-time through the change of wafer curvature using the in-situ deflectometer. The epitaxy of GaN with AlN/GaN SL layers was performed on 200 mm Czochralski (CZ) on-axis Si {111} substrates 1.0 mm thick, as shown in FIG. 2(a). Crack-free 2-μm-thick bulk GaN cap layers were formed over the SL structure, which was over an AlN seed layer and a buffer structure composed of a multiple AlₓGa₁₋ₓN layers, where 0<x<1, having differing ratios of Al and Ga, with the Al greatest closest to the AlN seed layer and the Ga greatest closest to the SL structure. In an exemplary implementation, the buffer structure was composed of layers of Al_{0.75}Ga_{0.25}N, Al_{0.50}Ga_{0.50}N, and Al_{0.25}Ga_{0.75}N, although in other implementations, more layers (e.g., 5 layers) are present and/or the elemental distribution is different.

An example of the evolution of wafer curvature during growth is shown in FIG. 2(b). Wafer curvature became negative (concave) during the growth of AlN/AlGaN seed layer/buffer structure, due to the tensile stress of the film. After growth of the seed layer and buffer structure, curvature varied linearly with the thickness of the AlN/GaN SL layers over the growth time. Compressive stress built up during the growth of the bulk GaN layer and the curvature became positive with a convex wafer bow. The convex curvature decreased during the cool-down due to large tensile stresses resulting from the mismatch in CTE between the Si and grown epi-layers.

The crystalline quality of GaN epitaxial films was measured using high resolution X-Ray Diffraction (HRXRD) along the (002) and (102) directions. Triple-axis coupled omega-2 theta scan along the GaN (004) direction was used to determine the period thickness and interface roughness of the SLs. Surface morphology was studied by Atomic Force Microscope (AFM) and the cross-sections of samples were characterized by high resolution Transmission Electron Microscope (TEM). Post-deposition wafer bow was characterized by wafer stress measurement at room temperature.

A thick GaN cap layer was applied over the superlattice structure stack; this GaN layer was at least 1 micrometer thick, in some implementations about 2 micrometers thick.

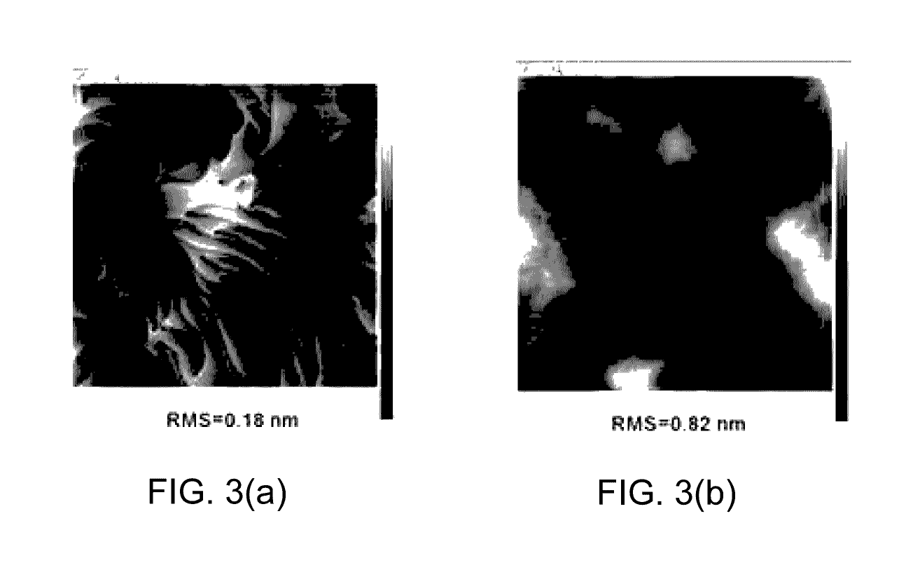

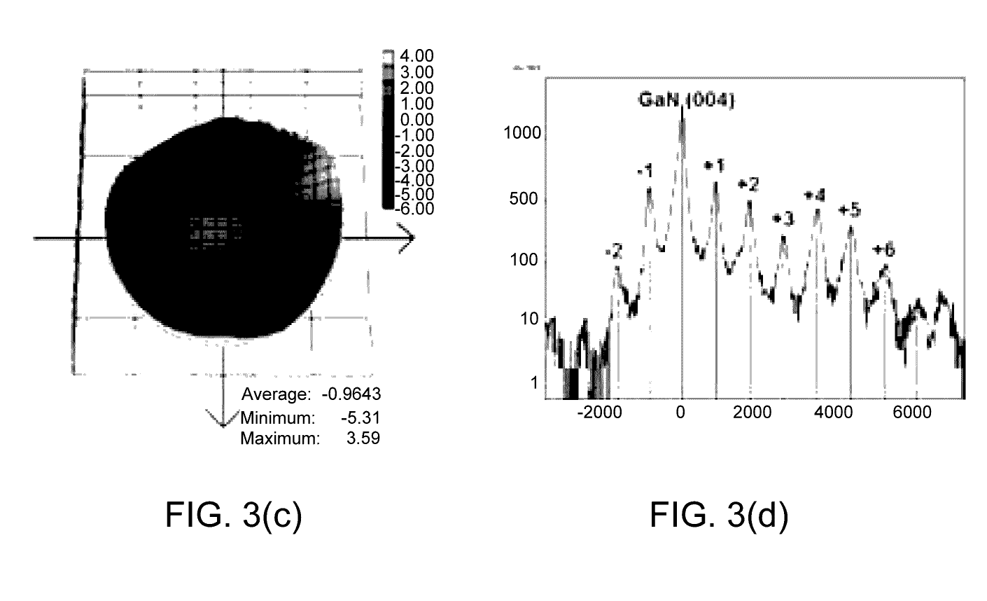

For a 2-μm stack GaN over AlN/GaN SL layers, smooth surfaces were observed by AFM with roughness of, e.g., 0.18 nm in a 5×5 μm² scan and, e.g., 0.82 nm in a 20×20 μm² scan, as shown in FIGS. 3(a) and 3(b). The dislocation density based on the surface pits from AFM was about 4×10⁻⁸/cm². As FIG. 3(b) shows, wafer bow at room temperature (RT) was in the range of <±10 μm. XRD rocking curves showed FWHM for GaN {002} and {102} 352 and 375 arc sec, respectively. Triple-axis coupled omega-2 theta scan along GaN {004} show up to +6^{th} satellite peak, indicating smooth interfacial quality for the AlN/GaN SL layers, as seen in FIG. 3(c). The period thickness was fitted as 4 nm AlN/17 nm GaN from the XRD omega-2 theta scan.

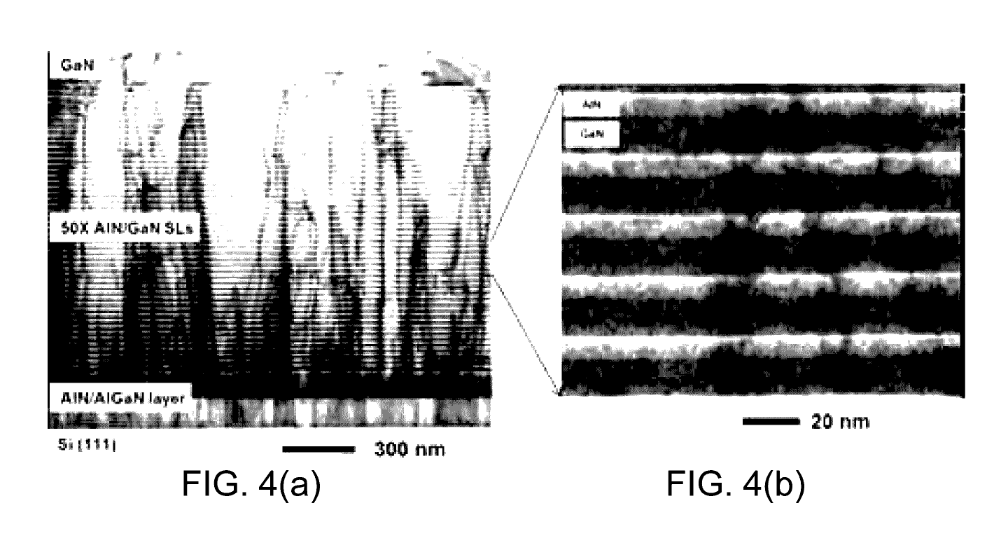

It was found that AlN/GaN SL layers are effective for dislocation filtering along the growth direction. FIG. 4(a) is the cross section TEM image, showing termination of threading dislocations towards the top-portion of the SLs. FIG. 4(b) shows a magnified view of the AlN/GaN SL layers with period thickness ˜22 nm.

Effect of GaN and AlN Thickness on Wafer Stress

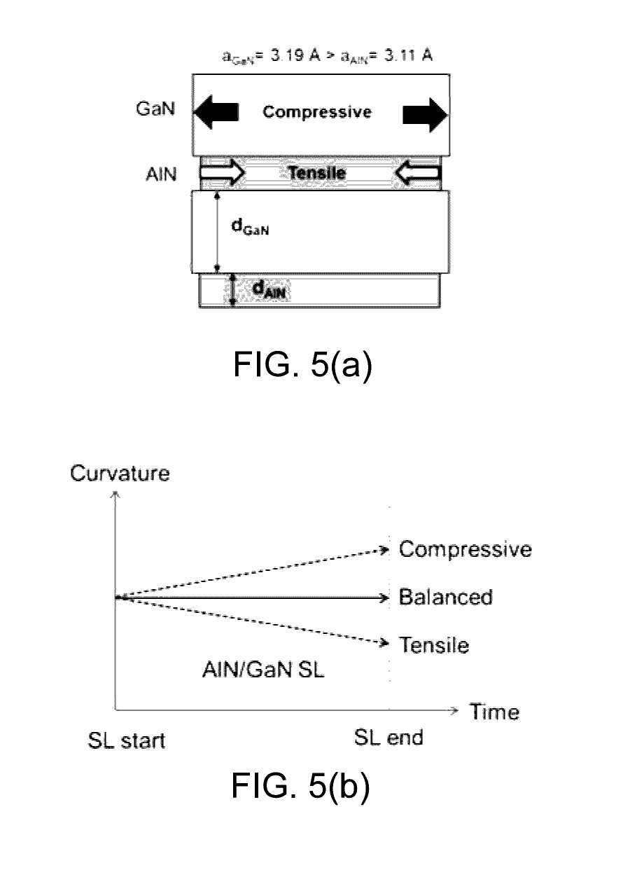

Due to the difference in the lattice constant between GaN and AlN, pseudomorphic growth of thin layers of GaN and AlN in the SLs lead to different stress levels within the GaN and AlN layers. In the case of a GaN layer grown on top of an AlN layer, GaN will experience compressive stress due to its larger lattice constant (a=3.19 Å) compared to that of AlN (a=3.11 Å). Conversely, AlN will have tensile stress when grown on top of a GaN layer, as illustrated in FIG. 5(a). During growth of the superlattice layers, the wafer curvature changes linearly with the increase of pair thickness of the superlattice layers, as the overall stress is the accumulation from individual AlN and GaN layers. If the slope of the curvature increase is positive, the overall stress for SLs is compressive; a negative slope of curvature change indicates tensile stress in the structure, and flat slope signifies balanced stress at growth temperature, as pictured in FIG. 5(b). Since the final residual stress for the top GaN layer after cooling down is affected by the stress build-up in the SLs, stress engineering is possible by controlling the periodicity in the SLs.

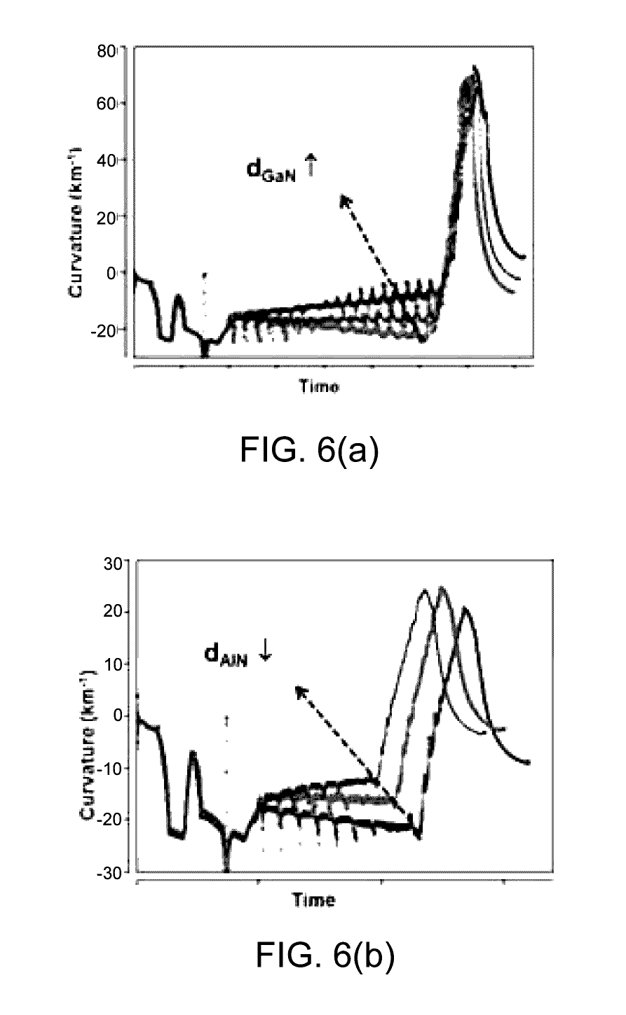

By adjusting the thickness of AlN and GaN layers, the stress of the superlattice structure can be controlled accordingly. Using a constant thickness for AlN layer and increasing the GaN thickness resulted in more compressive stress in the superlattice structure. As illustrated in FIG. 6(a), the slope of the wafer curvature increased with the increase in GaN thickness, indicating more compressive stress build-up in the superlattice structure. For constant thickness of GaN, the decrease in AlN thickness resulted in more compressive stress and increased rate of curvature change, as shown in FIG. 6(b). Wafer curvature/bow after cool down is determined by the stress level built into the superlattice structure.

Effect of Growth Conditions on Wafer Stress

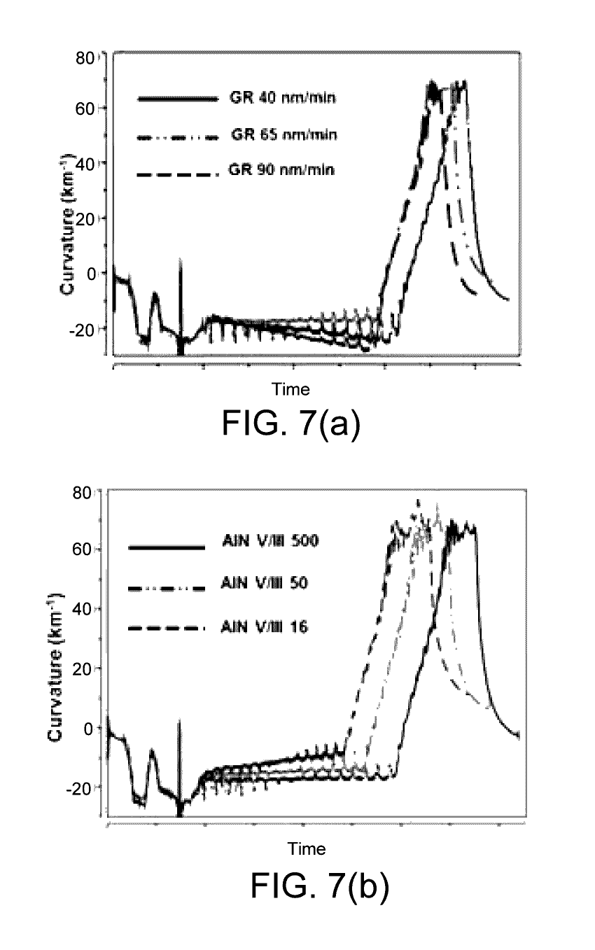

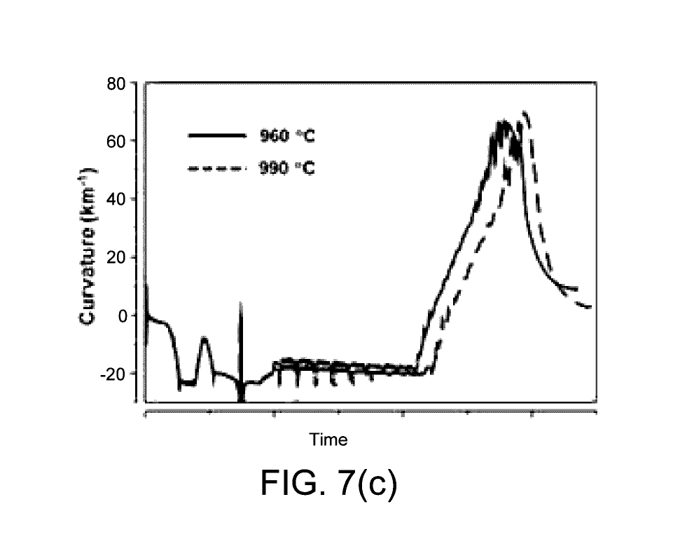

At constant period thickness, the growth conditions of GaN and AlN affect the stress in the SLs. FIG. 7(a) shows the curvature evolution for the superlattice structure with different growth rates (GR) of the GaN layer. As the growth rate of GaN increased between 40 nm/min and 65 nm/min, more compressive stress tended to build up. The experiment was carried out at constant GaN thickness of 17 nm. The trend reversed and tensile stress started to build up by further increasing GaN GR to 90 nm/min. At constant TMAl flow of 300 μmol/min, the growth rate of AlN increased with lower NH₃ or V/III ratio. At constant period thickness for both AlN and GaN in the superlattice structure, more compressive stress was built up by lowering the V/III ratio (higher AlN growth rate), as plotted in FIG. 7(b).

The effect of growth temperature was tested between 960 and 990° C. as measured by pyrometer on the Si surface. Growth rates increased with decreasing growth temperature. By adjusting growth time and maintaining constant period thickness, no significant difference in the stress of superlattice structure was observed within the temperature range tested.

The above specification provides a complete description of the structure and use of exemplary implementations of the invention. The above description provides specific implementations. It is to be understood that other implementations are contemplated and may be made without departing from the scope or spirit of the present disclosure.

For example, other base substrates other than silicon (Si) {111} may be used. In general, the base wafer and the superlattice structure have a mismatch. Any seed layer may be used, but typically is a mismatch with the base substrate.

Superlattice layer materials other than AlN and GaN may be used, and any additives or dopants may be included. The lattice constants of the two superlattice layer materials can differ by as little as 0.01 Å, or, the two lattice constants may differ by as little as 1%, or 2%. The thicknesses of the superlattice layers may be anywhere from, e.g., 1 nm to 50 nm. Typically, one of the superlattice material layers will be thicker than the other, although this is not required. For the particular implementation provided above, the material with the larger lattice constant (which thus produces compressive strength to the superlattice structure) is the thicker layer, although in other implementations the material with the smaller lattice constant may be the thicker layer. The superlattice layers are generally present as pairs (i.e., for each layer of a material there is one layer of the other material), however in some implementations, more layers of one of the superlattice materials may be present. In some implementations, the superlattice structure may have a third material present. The third material may provide, e.g., a compressive stress, a tensile stress, or be neutral. Any third layer may alternate with the other superlattice layers in any pattern, e.g., A-B-C-A-B-C . . . , A-B-C-B-A-B-C-B-A . . . , etc. Other variations of the superlattice structure are available.

The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about.” Accordingly, unless indicated to the contrary, any numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

What is claimed is:

1. A semiconductor material comprising:
a substrate;
a seed layer on the substrate;
a superlattice structure on the seed layer, wherein the superlattice structure comprises a plurality of superlattice layers (a) gallium nitride (GaN) and (b) layers selected from the group consisting of aluminum nitride (AlN), Al_{y}Ga_{1-y}N, where 0<y<1, and mixtures thereof, the superlattice layers arranged in any order; and
a cap layer formed on the superlattice structure.

2. The semiconductor material of claim 1, further comprising a buffer structure between the seed layer and the superlattice structure, the buffer structure comprising three or more distinct layers of AlₓGa₁₋ₓN, where 0≦x≦1.

3. The semiconductor material of claim 2, wherein the superlattice structure comprises alternating layers of GaN and AlN.

4. The semiconductor material of claim 3, wherein the AlN layer of the superlattice structure is in contact with the buffer structure.

5. The semiconductor material of claim 3, wherein the GaN layer of the superlattice structure is in contact with the buffer structure.

6. The semiconductor material of claim 3, wherein the GaN layer of the superlattice structure is in contact with the cap layer.

7. The semiconductor material of claim 3, wherein the superlattice structure comprises at least 50 pairs of layers.

8. The semiconductor material of claim 3, wherein the superlattice structure comprises 50 to 100 pairs of layers.

9. The semiconductor material of claim 3, wherein the AlN layer of the superlattice structure has a thickness of about 3 to 5 nm.

10. The semiconductor material of claim 3, wherein the GaN layer of the superlattice structure has a thickness of about 10 to 30 nm.

11. The semiconductor material of claim 3, wherein a ratio of the thickness of the AlN layer of the superlattice structure to the GaN layer of the superlattice structure is 1:2 to 1:10.

12. The semiconductor material of claim 2, wherein the superlattice structure comprises at least three layers in any order of (a) GaN and (b) layers selected from the group consisting of AlN, Al_{y}Ga_{1-y}N, where 0<y<1, and mixtures thereof.

13. The semiconductor material of claim 12, wherein the superlattice structure comprises at least 50 sets of layers.

14. The semiconductor material of claim 12, wherein the superlattice structure comprises 50 to 100 sets of layers.

15. The semiconductor material of claim 1, wherein the superlattice structure comprises alternating layers of GaN and AlN.

16. The semiconductor material of claim 15, wherein the AlN layer of the superlattice structure is in contact with the seed layer.

17. The semiconductor material of claim 15, wherein the GaN layer of the superlattice structure is in contact with the seed layer.

18. The semiconductor material of claim 1, wherein the superlattice structure comprises a plurality of layers in any order of (a) GaN and (b) layers selected from the group consisting of AlN, Al_{y}Ga_{1-y}N, where 0<y<1, and mixtures thereof.

19. The semiconductor material of claim 1, wherein the superlattice structure comprises at least three layers in any order of (a) GaN and (b) layers selected from the group consisting of AlN, Al_{y}Ga_{1-y}N, where 0<y<1, and mixtures thereof.

20. A semiconductor material consisting essentially of:
a silicon (Si) substrate;
an AlN seed layer on the Si substrate;
a buffer structure on the seed layer, wherein the buffer structure comprises three or more distinct layers of AlₓGa₁₋ₓN, where 0<x<1;
a superlattice structure on the buffer structure, wherein the superlattice structure comprises a plurality of layers in any order of (a) gallium nitride (GaN) and (b) layers selected from the group consisting of aluminum nitride (AlN), Al_{y}Ga_{1-y}N, where 0<y<1, and mixtures thereof; and
a cap layer formed on the superlattice structure.

21. The semiconductor material of claim 20, wherein the superlattice structure comprises alternating layers of GaN and AlN.

22. The semiconductor material of claim 20, wherein the superlattice structure comprises at least three layers in any order of (a) GaN and (b) layers selected from the group consisting of AlN, Al_{y}Ga_{1-y}N, where 0<y<1, and mixtures thereof.

23. A semiconductor material comprising:
a substrate;
a seed layer on the substrate;
a superlattice structure on the seed layer comprising a plurality of superlattice layers, each of the superlattice layers comprising one or more of Al, Ga, N, with at least one of the plurality of superlattice layers providing compressive stress and at least one of the plurality of superlattice layers providing tensile stress; and
a cap layer formed on the superlattice structure, the cap layer comprising one or more of Al, Ga, N, and being lattice matched with the superlattice structure.

24. The semiconductor material of claim 23 further comprising a buffer structure having distinct multiple layers comprising one or more of Al, Ga, N formed between the seed layer and the superlattice structure.

25. The semiconductor material of claim 24, wherein the plurality of superlattice layers is a pair of superlattice layers.

26. The semiconductor material of claim 25, wherein the one of the superlattice layers of the pair has a lattice constant that is larger than a lattice constant of the other of the superlattice layers.

27. The semiconductor material of claim 26, wherein the one of the superlattice layers of the pair has a lattice constant at least 0.01 Å larger than the lattice constant of the other of the superlattice layers.

28. The semiconductor material of claim 25, wherein the one of the superlattice layers of the pair has a thickness that is greater than a thickness of the other of the superlattice layers.

29. The semiconductor material of claim 28, wherein the one of the superlattice layers of the pair has a thickness at least 3 nm thicker than the other of the superlattice layers.

30. The semiconductor material of claim 24, wherein the plurality of superlattice layers is in any order of (a) gallium nitride and (b) layers selected from the group consisting of aluminum nitride, Al_{y}Ga_{1-y}N, where 0<y<1, and mixtures thereof.
